(19) United States
(12) Patent Application Publication
(10) Pub. No.: US 2004/0058531 A1
(43) Pub. Date: Mar. 25, 2004

(54) Method for preventing metal extrusion in a semiconductor structure.

(75) Inventors: Yen-Wu Hsieh, Yang-Mei Chen (TW); Shih-Lung Lee, Hsin-Chu City (TW); Ber Wu, Hsin-Yen Chen (TW); Wen-Shan Wei, Taipei (TW)

Correspondence Address: LOWE, HAUPTMAN, GOPSTEIN & BERNER, LLP, Suite 310, 1700 Diagonal Road, Alexandria, VA, 22314, US

(73) Assignee: UNITED MICROELECTRONICS CORP.

(21) Appl. No.: 10/214,145

(22) Filed: Aug. 8, 2002

(51) Int. Cl. H01L 21/4763

(52) U.S. Cl. 438/689

(57) ABSTRACT

A method for preventing metal extrusion in a semiconductor structure is disclosed in this present invention. The point of this invention is that the first metal is suffered to a thermal process before the fabrication of a conformal glue layer into a via onto the first metal layer, and thus the first metal layer will not be extruded by thermal effect any more during the following processes. Therefore, this invention can provide a more efficient method for preventing metal extrusion in a semiconductor structure, and the phenomenon of the raising resistance caused by the metal extrusion can be avoided thereby.

### BACKGROUND OF THE INVENTION

1. Field of the Invention

This present invention relates to a method for preventing metal extrusion, and more particularly to a method for preventing metal extrusion in semiconductor structure.

2. Description of the Prior Art

In semiconductor structure, metal contact plays a very important role. The metal contacts can connect semiconductor device through metal layers. In the view of one having ordinary skill in the art, metal contacts are usually formed by the follow methods. One method for forming metal contact is “through ARC”. The “through ARC” means the metal via is through the anti-reflection coating (ARC) on the metal layer. As shown in FIG. 1, an anti-reflecting coating 110 is on a first metal layer 100. A dielectric layer 120 is blanketed onto the first metal layer 100 and the anti-reflection coating 110. After a etching step, a via 130 is fabricated through the dielectric layer 120 and the anti-reflecting coating 110, and thus portion of the first metal layer 100 is exposed by the via 130. Subsequently, a glue layer 140 is deposited into the via 130, and a secondary metal layer 150 is filled filled into the via 130.

Another well-known process for fabricating a metal contact in a semiconductor structure is as shown in FIG. 2. In contrast with the above-mentioned method, the etching process for forming the via 130 is stopped on the ARC 110, and the first metal layer 100 will not be exposed by the via 130.

However, there are many problems in the above-mentioned methods. In the method of “through ARC”, during the formation of the glue layer and the secondary metal layer, the first metal layer 100 will be extruded by the thermal effect and some unwanted reaction may be occurred. In the case of aluminum as the first metal layer 100 and tungsten as the secondary metal layer 150, during the formation of the glue layer 140 and the secondary metal layer 150, the first metal layer 100 will be extruded through the glue layer 140. Moreover, when the secondary metal layer 150 is fabricated by chemical vapor deposition (CVD) with WF₄, the side-reaction between the extruded aluminum and WF₄ will occur, as the following reaction 1, and the resistance of the semiconductor structure will be raised by the produce 160 of the reaction 1.

WF₄+Al→AlF₃ (reaction 1)

On the other hand, in the above-mentioned method of “stop on ARC”, the reaction 1 will not occur, but the average resistance of the semiconductor structure is higher than the resistance of the semiconductor structure employing the method of “through ARC”. Ordinarily, the method of “through ARC” is utilized wider than the method of “stop on ARC”. Hence, it is important to develop an efficient method for preventing the metal extrusion of the method of “through ARC” in a semiconductor structure.

### SUMMARY OF THE INVENTION

In accordance with the present invention, a method is provided for preventing metal extrusion during the formation of a metal contact in a semiconductor structure. The phenomenon of raising resistance in a semiconductor structure can be efficient removed by preventing the metal extrusion during the formation of a metal contact.

In accordance with the above-mentioned objects, the invention provides a method for preventing metal extrusion in a semiconductor structure. Due to a thermal process before the formation of the glue layer into a metal via, the phenomenon of metal extrusion in a semiconductor structure can be precluded efficiently. Therefore, this invention provides a method for keeping a semiconductor structure from raising resistance by preventing metal extrusion during the formation of the metal contact.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a diagram showing a metal contact fabricated by the method of “through ARC” in the prior art;

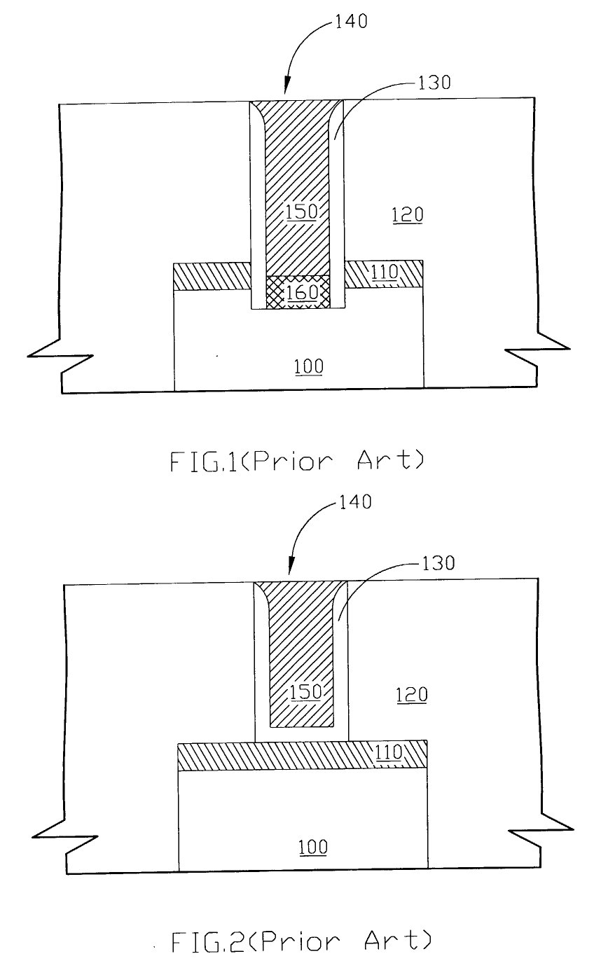

FIG. 2 is a diagram showing a metal contact fabricated by the method of “stop on ARC” in the prior art;

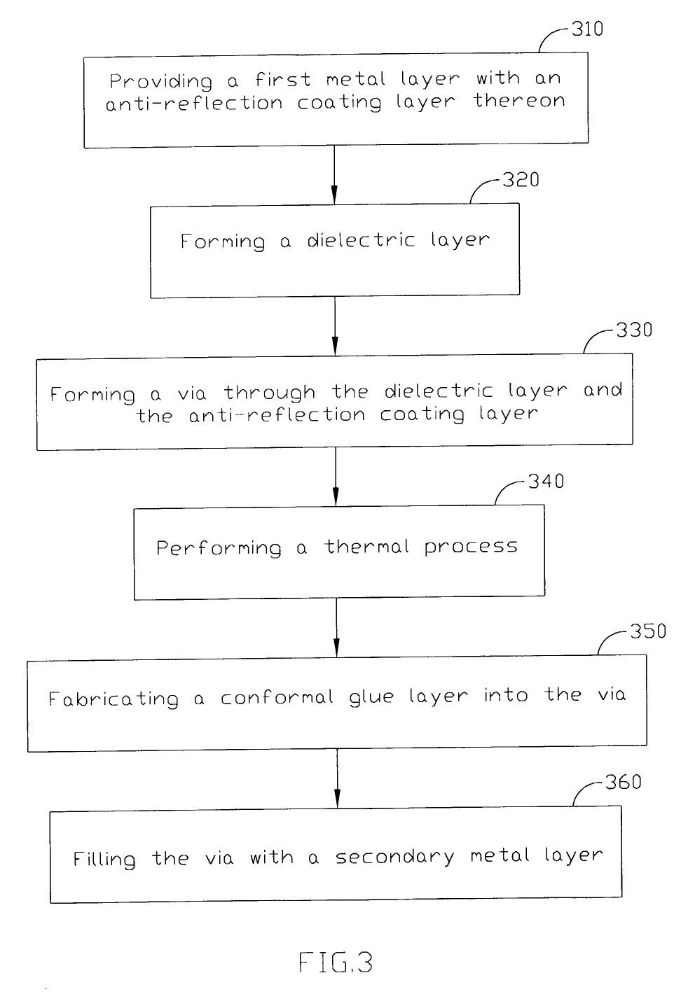

FIG. 3 is a flow chart showing the method for preventing metal extrusion in a semiconductor structure according to this present invention; and

FIGS. 4A to 4C show the method for preventing metal extrusion in a semiconductor structure according to this invention.

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

One preferred embodiment of this invention is a method for preventing metal extrusion. At first, a first metal layer with an anti-reflection coating layer thereon is provided on a substrate. A dielectric layer is blanketed onto the substrate and the anti-reflection coating layer. After an etching step, a via is formed through the dielectric layer and the anti-reflection coating layer, and portion of the first metal layer is exposed by the via. Subsequently, a thermal process is performed to extrude the first metal layer. The temperature of the above-mentioned thermal process is equal to/higher than the highest temperature of the following process. Following the thermal process, a conformal glue layer is formed into the via. Finally, the via is filled with a secondary metal layer. Because the thermal process is performed before the formation of the glue layer and the secondary metal layer, the first metal layer will not be extruded by thermal effect during the following processes.

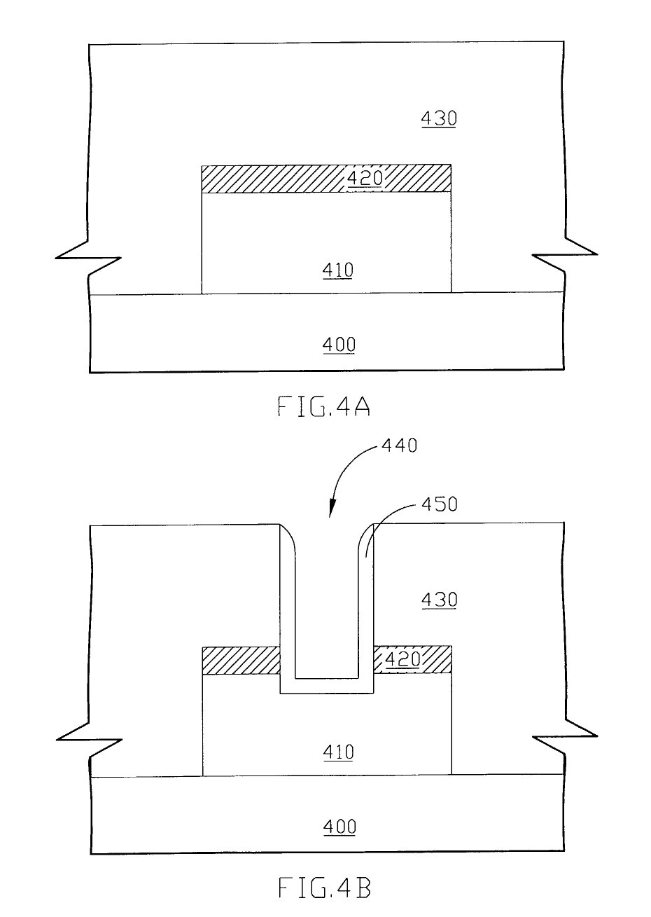

Another preferred embodiment according to this present invention is a method for preventing metal extrusion in a semiconductor structure. FIG. 3 is a flowchart of the above-mentioned method for preventing metal extrusion. At first, a first metal layer with an anti-reflection coating layer thereon is provided on a substrate, as the step 310. The first metal layer may be aluminum (Al). The anti-reflection coating layer may be consisted of a Ti layer and a TiN layer. As shown in the step 320, a dielectric layer is blanketed onto the substrate and the anti-reflection coating layer. The dielectric layer may be SiO₂, low-K dielectric material, or other dielectric materials.

Next, the dielectric layer and the anti-reflection coating layer are etched, as the step 330, and a via is fabricated through the dielectric layer and the anti-reflection coating layer. After the formation of the via, part of the first metal layer is exposed by the via. Subsequently, a thermal process is performed as shown in the step 340. In order to prevent the extrusion of the first metal layer by thermal effect during the following process, the temperature of the thermal process in step 340 may be equal to/or higher than the temperature while the formation of the first metal layer. Preferably, the temperature of the thermal process in step 340 is equal to/or higher than the highest temperature during the following processes.

After the thermal process, a conformal glue layer is fabricated into the via, as step 350. The glue layer may comprise a Ti layer and a TiN layer. Finally, as shown in step 260, a secondary metal layer is filled into the via, and the unwanted secondary metal layer is removed by a ordinary technology as chemical mechanical polishing (CMP). The secondary metal layer may be tungsten (W), or other conductive materials.

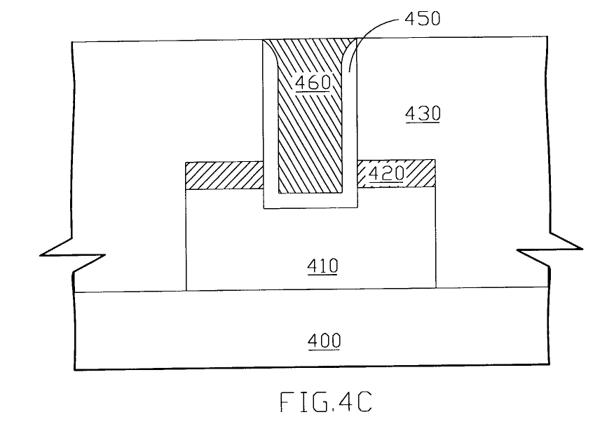

Another preferred embodiment of this present invention is a method for preventing metal extrusion in a semiconductor structure. Referred to FIG. 4A, a first metal layer 410 is provided on a semiconductor substrate 400, and an anti-reflection coating layer 420 is formed onto the first metal layer 410. A dielectric layer is blanketed onto the substrate 400 and the anti-reflection coating layer 420. In this manner, the first metal layer 410 may be consisted of aluminum, or other conductive materials. The anti-reflection coating layer 420 may comprise a Ti layer and a TiN layer, wherein the thickness of the Ti layer is 50˜250 angstrom and the thickness of the TiN layer is 200˜400 angstrom. The dielectric layer 430 comprises SiO₂, low-K dielectric material, or the other dielectric materials.

Subsequently, the dielectric layer 430 and the anti-reflection coating layer 420 are etching for fabricating a via 440 through the dielectric layer 430 and the anti-reflection coating layer 420, and portion of the first metal layer 410 is exposed by the via 440. After fabricating the via 440, an important step of this present invention is performed. In order to prevent the extrusion of the first metal layer 410 during the following process, the first metal layer 410 is suffered to a thermal process. Next, a conformal glue layer 450 is fabricated into the via 440, as shown in FIG. 4B. The glue layer 450 may comprises a Ti layer and a TiN layer.

The temperature of the above-mentioned thermal process before the formation of the glue layer 450 is a key of this present invention. Preferably, the temperature of the above-mentioned thermal process is equal to/or higher than the temperature during the formation of the first metal layer. More preferably, the temperature of the above-mentioned thermal process is equal to/or higher than the temperature of the processes after the step for forming the via. For example, if the highest temperature during the following processes is the temperature of the glue layer 450 formation at 700˜800 degree C., the temperature of the above-mentioned thermal process may be set at 700˜800 degree C. or higher.

As shown in FIG. 4C, a secondary metal layer 460 is filled into the via 440, and the unwanted secondary metal layer 460 is removed by the technology in the prior art, such as chemical mechanical polishing. The secondary metal layer 460 may be tungsten (W), or the like. The secondary metal layer 460 is formed by chemical vapor deposition (CVD), or other ordinary process.

According to this preferred embodiment, because the first metal layer is suffered to a thermal process before the fabricating of the glue layer, the extrusion of the first metal layer will not occur by thermal effect during the following processes. Thus, the side-reaction between the first metal layer and the material of the secondary metal layer as above-cited in the prior art will not happen during the formation of the secondary metal layer, and the resistance of the semiconductor structure according to this present invention will not be raised.

According to the preferred embodiments, this present invention discloses a method for preventing metal extrusion in a semiconductor structure. The first metal layer is suffered to a thermal process before fabricating a conformal glue layer into a via, wherein portion of the first metal layer is exposed by the via. Because the temperature of the above-mentioned thermal process is equal to or higher than the highest temperature during the following processes, the first metal layer will not be extruded any more by thermal effect during the following processes. Moreover, the method according to this present invention can keep the first metal layer from the side-reaction during the formation of the secondary metal layer into the via. Thus, this invention provides an efficient method for preventing the raising of the resistance in a semiconductor structure due to metal extrusion.

Although specific embodiments have been illustrated and described, it will be obvious to those skilled in the art that various modifications may be made without departing from what is intended to be limited solely by the appended claims.

What is claimed is:

1. A method for preventing metal extrusion, comprising:
providing a first metal layer;
forming a dielectric layer onto said first metal layer;
etching said dielectric layer to form a via onto said first metal layer;
performing a thermal process; and
depositing a conformal glue layer into said via.

2. The method according to claim 1, further comprises forming a anti-reflection coating layer onto said first metal layer before the step for forming said dielectric layer.

3. The method according to claim 2, wherein said via is through said dielectric layer and said anti-reflection coating layer.

4. The method according to claim 1, wherein said thermal process is performed at a temperature higher than the temperature during said step for providing said first metal layer.

5. The method according to claim 1, wherein said thermal process is performed at a temperature equal to the highest temperature during a plurality of process following the step for etching said dielectric layer.

6. The method according to claim 1, wherein said thermal process is performed at a temperature higher than the highest temperature during a plurality of process following the step for etching said dielectric layer.

7. The method according to claim 1, further comprises filling said via with a secondary metal layer.

8. A method for preventing metal extrusion in a semiconductor structure, comprising:
providing a first metal layer with an anti-reflection coating layer thereon;
forming a dielectric layer onto said anti-reflection coating layer;
etching said dielectric layer and said anti-reflection coating layer to form a via exposing said first metal layer;
performing a thermal process;
depositing a conformal glue layer into said via; and
filling said via with a secondary metal layer.

9. The method according to claim 8, wherein said thermal process is performed at a temperature higher than the temperature of said step for providing said first metal layer.

10. The method according to claim 8, wherein said thermal process is performed at a temperature equal to the highest temperature during a plurality of process following the step for etching said dielectric layer and said anti-reflection coating layer.

11. The method according to claim 8, wherein said thermal process is performed at a temperature higher than the highest temperature during a plurality of process following the step for etching said dielectric layer and said anti-reflection coating layer.

12. The method according to claim 8, wherein said first metal layer is aluminum.

13. The method according to claim 8, wherein said anti-reflection coating layer comprises a Ti layer.

14. The method according to claim 8, wherein said anti-reflection coating layer comprises a TiN layer.

15. The method according to claim 8, wherein said secondary metal layer is tungsten.

16. A method for preventing metal extrusion in a semiconductor structure, comprising:
providing an aluminum layer on a substrate;
forming an anti-reflection coating layer onto said aluminum layer;
forming a dielectric layer onto said substrate and said anti-reflection coating layer;
etching said dielectric layer and said anti-reflection coating layer to form a via exposing said aluminum layer;
performing a thermal process;
depositing a conformal glue layer into said via; and
filling said via with a tungsten layer.

17. The method according to claim 16, wherein said thermal process is performed at a temperature higher than the temperature of said step for providing said aluminum layer.

18. The method according to claim 16, wherein said thermal process is performed at a temperature equal to the highest temperature during a plurality of process following the step for etching said dielectric layer and said anti-reflection coating layer.

19. The method according to claim 16, wherein said thermal process is performed at a temperature higher than the highest temperature during a plurality of process following the step for etching said dielectric layer and said anti-reflection coating layer.

20. The method according to claim 16, wherein said glue layer comprises a Ti layer.

21. The method according to claim 16, wherein said glue layer comprises a TiN layer.
